(19) United States
(12) Patent Application Publication
(10) Pub. No.: US 2026/0075887 A1
(43) Pub. Date: Mar. 12, 2026

(54) TRENCHED DIODE HAVING ENHANCED FORWARD VOLTAGE DROP TO REVERSE LEAKAGE CURRENT TRADEOFF AND METHOD OF FORMING SUCH DEVICE

(71) Applicant: Wolfspeed, Inc., Durham, NC (US)

(72) Inventors: Rahul R. Potera, Apex, NC (US); Jae-Hyung Park, Apex, NC (US); Shadi Sabri, Cary, NC (US); In-Hwan Ji, Apex, NC (US); Neal Oldham, Apex, NC (US); Thomas Harrington, Carrollton, TX (US)

(21) Appl. No.: 18/830,713

(22) Filed: Sep. 11, 2024

(51) Int. Cl. H01L 29/06; H01L 29/45; H01L 29/47; H01L 29/66; H01L 29/872

(52) U.S. Cl. CPC H10D 62/107; H10D 8/051; H10D 8/605; H10D 62/83; H10D 64/62; H10D 64/64

(57) ABSTRACT

A Schottky diode includes a drift layer of a first conductivity type, a trench in the drift layer, first implanted regions having a second conductivity type in sidewalls of the trench, a second implanted region having the second conductivity type in a bottom of the trench, and a metal in the trench. The first implanted regions have a first doping concentration and the second implanted region has a second doping concentration, wherein the first doping concentration is different than the second doping concentration.

### FIELD

The present invention relates generally to power semiconductor devices and, more particularly, to trenched diode devices and methods of fabricating such devices.

### BACKGROUND

Silicon carbide (SiC) has many advantages over pure silicon in high-power applications, including higher operating temperature and operating at higher frequencies (since silicon devices are limited by gate charge and turn-on/off transients), thereby enabling even more system-level optimizations. Consequently, SiC Schottky diodes are a preferred choice of rectifiers in advanced power applications at 650 volts and above. However, as a result of a high electric field across the junction, due at least in part to imperfections at the metal-semiconductor interface and higher epitaxial doping level, SiC Schottky diodes generally exhibit higher reverse leakage current I_{R} compared to their pure silicon counterparts.

### SUMMARY

The present invention, as manifested in one or more embodiments, is directed generally to a Schottky diode that enhances a trade-off between forward voltage drop and reverse leakage current in the device. To achieve this, embodiments of the inventive concept lower the electric field present at the Schottky barrier junction using trench geometry. Embodiments of the inventive concept further provide a simple scheme for integrating a trenched junction barrier Schottky (JBS) active area, ohmic contacts and trenched floating guard rings into a SiC diode.

In accordance with one or more embodiments, a Schottky diode includes a drift layer of a first conductivity type, a trench in the drift layer, first implanted regions having a second conductivity type in sidewalls of the trench, a second implanted region having the second conductivity type in a bottom of the trench, and a metal in the trench. The first implanted regions have a first doping concentration and the second implanted region has a second doping concentration, wherein the first doping concentration is different than the second doping concentration. The drift layer may comprise first and second mesas that define the sidewalls of the trench, and the metal may be on upper surfaces of the first and second mesas to form Schottky contacts. The Schottky diode further includes an anode electrode on at least a portion of the Schottky contact and electrically connected to the Schottky contact, and a cathode electrode on at least a portion of a back surface of a substrate, under the drift layer, and electrically connected to the substrate.

In accordance with one or more embodiments, a method of forming a Schottky diode includes: providing a drift layer of a first conductivity type on a substrate; forming a trench in the drift layer; implanting sidewalls of the trench at a first doping concentration to form first implanted regions; implanting a bottom of the trench at a second doping concentration to form a second implanted region, wherein the first doping concentration is different than the second doping concentration; and forming a Schottky contact to the drift region. The drift layer may include an active region, a transition region and a termination region respectively adjacent in a second direction parallel to the upper surface of the substrate, wherein the trench may include a trenched JBS area formed in the active region, wherein the method may further include forming a plurality of trenched guard rings in the termination region, and wherein the trenched JBS area and the plurality of trenched guard rings are formed during a same processing step.

In accordance with one or more embodiments, a method of forming a semiconductor device includes: providing a drift layer that includes an active region, a transition region and a termination region; and concurrently forming trenches in the active region, the transition region, and the termination region. In some embodiments, The drift layer has a first conductivity type, and the forming the trenches may include: forming a trenched JBS area of a second conductivity type in the active region; forming a trenched doping area of the second conductivity type in the transition region; and forming a plurality of trenched guard rings of the second conductivity type in the termination region, wherein the trenched JBS area, the trenched doping area, and the plurality of trenched guard rings are integrated together on a single substrate using same processing steps.

In accordance with one or more embodiments, a semiconductor device includes: a semiconductor layer structure that includes a drift layer of a first conductivity type, the semiconductor layer structure including an active region, a transition region and a termination region respectively adjacent in a first direction parallel to an upper surface of the semiconductor layer structure; a first trench in the semiconductor layer structure in the active region; a second trench of the semiconductor layer structure in the transition region; a plurality of third trenches in the semiconductor layer structure in the termination region; first implanted regions having a second conductivity type in sidewalls of each of the first, second and third trenches; second implanted region having the second conductivity type in a bottom of each of the first, second and third trenches; and a metal in the first trench and in a portion of the second trench. The metal is on one of the first implanted regions in the second trench proximate the active region and on a portion of the second implanted region in the second trench, and the second trench is partially filled with a dielectric layer. In some embodiments, the dielectric layer is non-overlapping with the metal in a direction perpendicular to the upper surface of the semiconductor layer structure.

In accordance with one or more embodiments, a semiconductor device includes: a semiconductor layer structure including a drift layer of a first conductivity type, the drift layer including an active region, a transition region and a termination region adjacent in a direction parallel to an upper surface of the semiconductor layer structure; a first trench in the semiconductor layer structure in the active region; a second trench in of the semiconductor layer structure in the transition region; and a plurality of third trenches in the semiconductor layer structure in the termination region. The first, second and third trenches have equal depths, relative to the upper surface of the semiconductor layer structure.

Techniques of the present inventive concept can provide substantial beneficial technical effects. By way of example only and without limitation, techniques according to embodiments of the present disclosure may provide one or more of the following advantages, among other benefits:
improves a trade-off between forward voltage drop and reverse leakage current in a Schottky diode;
reduces the number of masks required for device fabrication by using a trench etch for alignment marks;
provides simple integration of trenched junction barrier Schottky (JBS) active areas, ohmic contacts and trenched floating guard rings in a termination region into a SiC diode using the same processing steps;
easily integrates with existing power semiconductor device fabrication processes without increasing device fabrication complexity;

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a schematic cross-sectional view depicting at least a portion of an illustrative planar SiC Schottky diode;

FIG. 2 is a schematic cross-sectional view depicting at least a portion of an illustrative trenched SiC Schottky diode, according to one or more embodiments of the present inventive concept;

FIG. 3 is a flow diagram depicting intermediate processes in an example method of fabricating a trench diode, according to one or more embodiments of the inventive concept; and FIGS. 4A-4J are schematic cross-sectional views depicting intermediate processes in the example method of fabricating a trench diode shown in FIG. 3, according to one or more embodiments of the inventive concept.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Due primarily to its low forward voltage drop and high switching speed, Schottky diodes are widely used in a variety of applications. Silicon carbide (SiC) semiconductor devices exhibit higher breakdown voltage, higher thermal conductivity, higher operating temperature, lower losses and low parasitic capacitance facilitating more efficient switching at high frequencies compared to silicon (Si) based power electronic devices. The superior performance characteristics of SiC based semiconductor devices has made SiC Schottky diodes a preferred choice of rectifiers in advanced power applications at 650 volts and above.

The electrical performance of a Schottky diode is subject to various physical trade-offs, such as, for example, between forward voltage drop V_{F}, reverse leakage current I_{R}, and reverse blocking voltage. A trench based Schottky diode may be considered as an improvement over its planar counterpart.

When considering forward voltage drop V_{F} in a Schottky diode, there are two primary components; namely, the voltage drop across the metal-semiconductor junction and the voltage drop across the drift layer in the device. The voltage drop across the metal-semiconductor junction may be controlled as a function of the type of Schottky metal used, with the Schottky barrier that is formed being the result of a difference between the metal work function and the electron affinity of the semiconductor material. By using a Schottky metal having a low metal work function, the voltage drop across the metal-semiconductor interface may be minimized. However, the amount of reverse leakage current I_{R} in the Schottky device is also determined primarily by the Schottky barrier and the electrical field across the metal-semiconductor interface; using a Schottky metal having a lower metal work function generally results in a higher reverse leakage current.

While leakage current can be reduced by increasing a thickness of the drift layer, this comes at the expense of higher ohmic and thermal resistance resulting in higher forward voltage drop V_{F}, which is disadvantageous in power applications and negates the benefits of using a low metal work function Schottky metal. Thus, there is a trade-off between forward voltage drop V_{F} and reverse leakage current I_{R} in a SiC diode, which is improved using a trenched JBS structure.

A trench based Schottky diode structure may be used to achieve improved reverse blocking voltage without significantly compromising a primary advantage of a Schottky diode in providing a low forward voltage drop V_{F}. Compared to a trench based Schottky diode structure, equipotential lines in a planar Schottky diode are generally crowded proximate a top electrode, thereby creating a high electric field concentration near the surface of the device. This results in an increase in reverse leakage current I_{R} with increasing reverse voltage, and an early breakdown when a critical electric field is exceeded near the surface of the device. By forming trenches in the drift layer and at least partially filling the trenches with a conductive material (e.g., metal, polysilicon, etc.), the trenches will deplete the drift layer in the reverse direction which results in a flattened electric field profile along a drift layer of the device. In this manner, the trenches may serve as a field plate, and may reduce reverse leakage current levels.

Aspects of the inventive concept, as manifested in one or more embodiments thereof, integrate trench based JBS shielding in an active region of a SiC diode and a trench-based termination region to thereby improve a trade-off between forward voltage drop V_{F} and reverse leakage current I_{R} in the device. Although the discussion below focuses primarily on SiC Schottky diode embodiments, it will be appreciated that the described embodiments are not limited to such devices, and that the same techniques may be used to form other trenched power semiconductor devices such as metal-oxide-semiconductor field-effect transistors (MOSFETs), insulated-gate bipolar transistors (IGBTs), gate-controlled thyristors and the like.

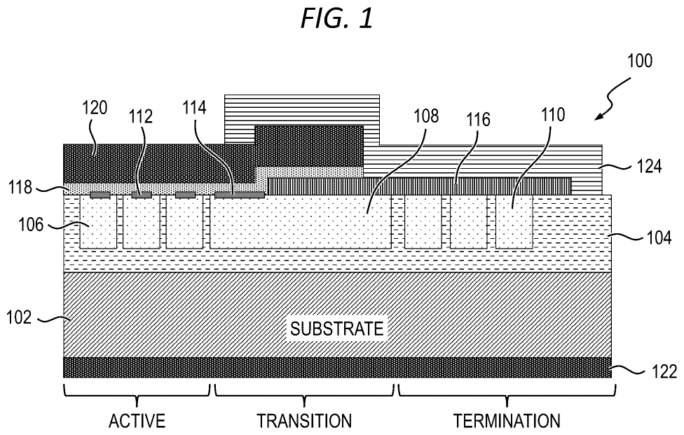

FIG. 1 is a schematic cross-sectional view depicting at least a portion of an illustrative planar SiC Schottky diode 100. Referring to FIG. 1, the SiC Schottky diode 100 includes a heavily-doped n-type (n⁺) SiC semiconductor substrate 102. A lightly-doped n-type (n⁻) SiC drift layer 104 is provided on an upper surface of the substrate 102. The Schottky diode 100 may be divided into an active region where the Schottky diode (and potentially other active devices) are formed, a termination region where device edge termination structures (e.g., guard rings) are formed, and a transition region between the active region and the termination region that serves as a transition area between the active and termination regions. The active region, transition region and termination region are adjacent in a horizontal direction parallel to an upper surface of the substrate 102.

A plurality of p-type regions 106 may be implanted into the drift layer 104 in the active region of the Schottky diode 100. Each of the p-type regions 106 extends partially into the drift layer 104 in a vertical direction perpendicular to the upper surface of the substrate 102 and are separated from one another in the horizontal direction.

A p-type region 108 may be formed in the drift layer 104 in the transition region of the Schottky diode 100. The p-type region 108 extends partially into the drift layer 104 in the vertical direction, with a first end of the p-type region 108 being adjacent an edge of the active region and a second end, opposite the first end, being adjacent an edge of the termination region in the horizontal direction. The p-type region 108 may act as a moat termination structure in the Schottky diode 100. A plurality of p-type guard rings 110 may be formed in the drift layer 104 in the termination region of the Schottky diode 100. The guard rings 110 extend partially in the drift layer 104 in the vertical direction and are separated from one another in the horizontal direction.

A plurality of metal-silicided ohmic contact regions 112 may be provided in the p-type regions 106, proximate an upper surface of the p-type regions 106. A metal-silicided ohmic contact region 114 may be provided in the p-type region 108, proximate an upper surface of the p-type region 108 and laterally adjacent the active region. The metal-silicided ohmic contact regions 112, 114 may be configured to improve surge current handling capability in the Schottky diode 100.

An insulating layer 116 may be provided on at least a portion of an upper surface of the drift layer 104 and on an upper surface of the guard rings 110 in the horizontal direction in the termination region. The insulating layer 116 may also extend onto a portion of the upper surface of the p-type regions 108 in the transition region adjacent the termination region. The insulating layer 116 will serve to electrically isolate the guard rings 110 and a portion of the p-type regions 108 from a subsequently formed Schottky metal/barrier layer.

A Schottky barrier or contact 118 is provided on at least a portion of the upper surface of the drift layer 104 and on the upper surface of the p-type regions 106 and the metal-silicided ohmic contact regions 112 in the active region. The Schottky contact 118 extends in the horizontal direction on the upper surface of the p-type regions 108 and the metal-silicided ohmic contact regions 114 in the transition region, and also on a sidewall and portion of an upper surface of the insulating layer 116 in the transition region. In one or more embodiments, the Schottky contact 118 may comprise a metal or metal silicide. The type of material selected for the Schottky contact 118 may depend upon the desired work function for the Schottky diode 100. Suitable materials for use as the Schottky contact 118 include, for example, molybdenum, platinum, chromium, tungsten, tungsten nitride, titanium, tantalum, titanium nitride, tantalum nitride, although embodiments are not limited thereto. The Schottky contact 118 electrically connects to the metal-silicided ohmic contact regions 112 and 114 and to the p-type regions 106 and 108.

The Schottky diode 100 further includes an anode electrode 120 and a cathode electrode 122. The anode electrode 120 may be provided on an upper surface of the Schottky contact 118 and is electrically connected to the Schottky contact 118. The cathode electrode 122 may be provided on a bottom surface of the substrate 102 and is electrically connected to the substrate 102. In one or more embodiments, the anode electrode 120 and the cathode electrode 122 may comprise a material providing a low-resistance electrical connection with the Schottky contact 118 and substrate 102, respectively, such as a metal or metal silicide. Anode electrode example materials may include aluminum, aluminum copper, or copper. Cathode electrode materials may include nickel silicide (NiSi), nickel (Ni), titanium (Ti), silver (Ag), copper (Cu), gold (Au) or combinations thereof.

The Schottky diode 100 may include a passivation layer 124 on a portion of the anode electrode 120 in the transition region, extending horizontally on the upper surface of the insulating layer 116 and drift layer 104 in the transition and termination regions of the Schottky diode 100. An opening in the passivation layer 124 is provided in at least a portion of the active region through which the anode electrode 120 is exposed for external electrical connection to the Schottky diode 100.

The p-type regions 106 may be formed by ion implantation into the drift layer 104 of the Schottky diode 100, forming a P-ohmic contact with the Schottky barrier/contact 118 at the Schottky anode and a P-ohmic contact with the metal-silicided ohmic contact regions 112 and 114, and a P-N junction with the lightly-doped SiC drift layer 104. In other words, the Schottky barrier/contact 118 forms ohmic contacts with underlying p-type SiC regions and forms Schottky contacts with underlying n-type SiC regions. This structure may be referred to as a merged PIN Schottky (MPS) diode arrangement. Under reverse bias, the depletion regions surrounding the p-type regions 106 will screen the high field strength from the Schottky contact 118, thereby reducing reverse leakage current I_{R} in the Schottky diode 100. The physical placement and area of the p-type regions 106 (relative to the overall size of the Schottky diode) and doping concentration, among other factors, will affect the performance characteristics of the Schottky diode 100, with forward voltage drop V_{F} traded against leakage and surge currents. As a result, the Schottky diode 100 may operate at a higher breakdown voltage with substantially the same leakage current and drift layer thickness.

An improvement to the Schottky diode 100 shown in FIG. 1 may be achieved using deep channeled implants or deep high energy implants for at least a subset of the p-type regions 106 for providing leakage current shielding. However, this improvement in the trade-off between forward voltage drop V_{F} and reverse leakage current I_{R} comes at the cost of using channeled implants which may add manufacturability challenges or high energy implants which may add manufacturing cost.

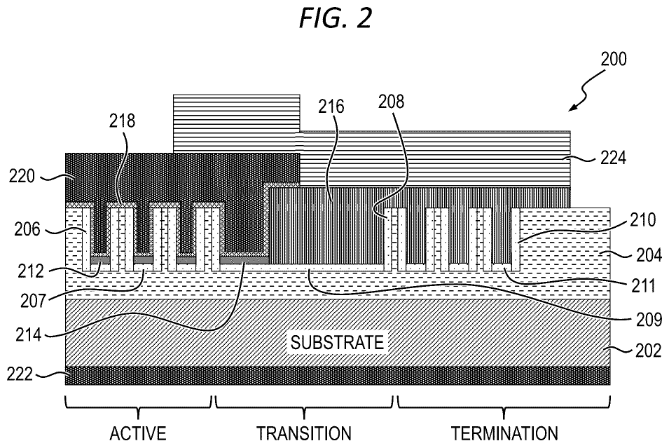

In accordance with aspects of the inventive concept, a Schottky diode is provided which lowers the electric field present at the junction between the Schottky contact and the drift layer using trench geometry while providing a simple scheme for integrating trenched JBS areas (i.e., trenches having p-type sidewalls and trench bottoms) in the active region, a trenched p-type region in the transition region, and trenched floating guard rings (i.e., field rings) in the termination region of the Schottky diode using the same processing steps. FIG. 2 is a schematic cross-sectional view depicting at least a portion of an illustrative trenched SiC Schottky diode 200, according to one or more embodiments of the present inventive concept. Referring to FIG. 2, The Schottky diode 200 includes a heavily-doped n-type (n⁺) SiC semiconductor substrate 202. A lightly-doped n-type (n⁻) SiC drift layer 204 is provided on an upper surface of the substrate 202, such as by using an epitaxial growth process.

In one or more embodiments, the substrate 202 may comprise, for example, a single crystal 4H silicon carbide semiconductor substrate that is heavily-doped with n-type impurities (i.e., an n⁺ silicon carbide substrate), although embodiments are not limited thereto. The impurities may comprise, for example, nitrogen or phosphorous. In example embodiments, the n-type substrate 202 may have a doping concentration of, for example, between about 1 [symbol] 10¹⁸ atoms/cm³ and 1 [symbol] 10²¹ atoms/cm³, although other doping concentrations may be used. The substrate 202 may be relatively thick in some embodiments (e.g., about 20μm-100 μm or more). It should be understood that while the substrate 202 may be depicted as a relatively thin layer, this is done merely to allow enlarging the thickness of other layers and regions shown in FIG. 2, and it will be appreciated that the substrate 202 will typically have a cross-sectional thickness that is much greater than what is shown. The thickness of various other layers and/or structures of the Schottky diode 200 likewise may not be shown to scale in order to provide enhanced clarity of the description.

In one or more embodiments, the drift layer 204 may be formed via an epitaxial growth process and is doped during growth. The n-type drift layer 204 may have, for example, a doping concentration of about 5 [symbol] 10¹⁵ atoms/cm3 to 5 [symbol] 10¹⁷ atoms/cm³. The drift layer 204 may be a thick region, having a vertical height above the substrate 202 of, for example, about 3 μm-50 μm, although embodiments are not limited thereto. In some embodiments, an upper portion of the drift layer 204 may have a higher doping concentration than a lower portion of the drift layer 204.

The Schottky diode 200, like the illustrative Schottky diode 100 shown in FIG. 1, may be conceptually divided into an active region where the Schottky diode (and possibly other active devices) are formed, a termination region where device edge termination structures (e.g., guard rings) and streets (e.g., scribe lines, etc.) are formed, and an transition region disposed between the active region and the termination region that serves as a transition area between the active and termination regions. The active region, transition region and termination region are adjacent in a horizontal direction parallel to an upper surface of the substrate 202.

One or more p-type JBS areas may be formed in the drift layer 204 in the active region of the Schottky diode 200. In one or more embodiments, each of the p-type JBS areas are formed as part of a trench structure, and therefore each of the JBS areas in the active region may be referred to herein as a trenched JBS area. Each of the trenched JBS areas includes p-type trench sidewalls 206 and a p-type trench bottom region 207. The trenched JBS areas extend partially into the drift layer 204 in a vertical direction, perpendicular to the upper surface of the substrate 202, and are separated from one another in the horizontal direction. Specifically, a plurality of trenches (i.e., active region trenches) may be etched in the upper surface of the drift layer 204 in the active region. A vertical depth of the trenches in the active region, from an upper surface of the drift layer 204, may be about 0.4μm-2.0 μm (e.g., about 1.0 μm-1.5 μm), a width of each of the active region trenches in the horizontal direction may be about 0.4 μm-2.0 μm (e.g., about 0.8 μm) and a spacing between adjacent active region trenches (also known as a mesa width) may be about 0.4 μm-2.0 μm, although embodiments are not limited thereto. The trenches may extend longitudinally substantially across the active region.

The p-type trench sidewalls 206 may be formed on vertical sidewalls of the active region trenches, for example using a tilted (i.e., angled) implant process (e.g., the ions are implanted at an angle in the range of about ±10-50 degrees from a line normal to the surface), and the p-type trench bottom regions 207 may be formed on a bottom of the active region trenches, for example using a vertical (i.e., 0 degree from normal) implant process. In one or more embodiments, a first doping concentration of the p-type trench sidewalls 206 may be different than a second doping concentration of the p-type trench bottom regions 207. By way of example only and without limitation, in one or more embodiments, the second doping concentration of the p-type doping of the trench bottom regions 207 may be comprised of multiple doping levels, including a heavily-doped p-type region and a lighter-doped p-type region which is below the heavily-doped p-type region. In other embodiments, the p-type doping of the trench bottom regions 207 may include only a heavily-doped p-type region. In other embodiments, the first and second doping concentrations of the p-type trench sidewalls 206 and p-type trench bottom regions 207, respectively, may be the same.

In one or more embodiments, the first doping concentration of the p-type trench sidewalls 206 may be chosen such that depletion regions, formed from the p-doping of the p-type trench sidewalls 206 of the mesas that define the trenches are able to fully deplete the n-type drift layer 204 in the center of the mesas in order to cut off Schottky diode leakage current originating from a Schottky diode formed by the interfaces between a Schottky layer 218 and the n-type drift layer 204 in the centers of the respective mesas. In this regard, the width of the n-type regions in the middle of each mesa (herein, these n-type regions may also be referred to as “mesa columns”) in the horizontal direction (i.e., the space between adjacent trenched JBS areas) may play an important role in the functionality of the device. In one or more embodiments, the width of each mesa column may be tightly coupled with doping of the p-type trench sidewalls 206 to allow the mesa column to be fully depleted during reverse-bias conditions in order to cut off Schottky leakage current in the device.

The doping concentration level of the p-type trench bottom regions 207 may be chosen to reduce a junction capacitance of the trenched JBS areas and thus the overall device capacitance. More particularly, in one or more embodiments, the doping concentration level of the p-type trench bottom regions 207 may be chosen such that the p-type trench bottom regions 207 will not be fully depleted under fully reverse-biased (i.e., full diode-blocking voltage) conditions; if the p-type trench bottom regions 207 becomes fully depleted, the junction capacitance will substantially increase. Thus, the doping of the p-type trench bottom regions 207 serves a different purpose than the doping of the p-type trench sidewall 206, and therefore the first and second doping concentrations may be independently controlled.

A p-type region may be formed in the drift layer 204 in the transition region. Like the trenched JBS areas, the p-type region may be formed as part of a trench structure extending partially into the drift layer 204 in the vertical direction, and may therefore be referred to herein as a trenched doping area. The trenched doping area includes p-type trench sidewalls 208 and a p-type trench bottom region 209. Specifically, a trench (i.e., transition region trench) may be etched into the drift layer 204 in the transition region at a vertical depth of, for example, about 0.4 μm-2.0 μm (e.g., about 1.0 μm-1.5 μm) from the upper surface of the drift layer 204, although embodiments are not limited thereto. The p-type trench sidewalls 208 may be formed on sidewalls of the transition region trench, for example using a tilted implant process (e.g., about ±10-50 degrees from a line normal to the surface), and the p-type trench bottom region 209 may be formed on a bottom of the transition region trench, for example using a vertical implant process. In one or more embodiments, a third doping concentration of the p-type trench sidewalls 208 may be different than a fourth doping concentration of the p-type trench bottom region 209. By way of example only and without limitation, in one or more embodiments, the fourth doping concentration of the p-type doping of the trench bottom regions 209 may be comprised of multiple doping levels, including a heavily-doped p-type region and a lighter-doped p-type region which is below the heavily-doped p-type region. In other embodiments, the fourth doping concentration of the p-type doping of the trench bottom regions 209 may include only a heavily-doped p-type region. In some embodiments, the third and fourth doping concentrations of the p-type trench sidewalls 208 and p-type trench bottom region 209, respectively, may be the same. The third doping concentration of the p-type trench sidewalls 208 in the transition region need not be the same as the first doping concentration of the p-type trench sidewalls 206 in the active region. Likewise, the fourth doping concentration of the p-type trench bottom region 209 in the transition region need not be the same as the second doping concentration of the p-type trench bottom regions 207 in the active region.

In one or more embodiments, the p-type trench sidewalls 208 of the p-type doping area and the p-type trench sidewalls 206 of the trenched JBS areas may be formed concurrently. Similarly, the p-type trench bottom region 209 of the p-type doping area and the p-type trench bottom region 207 of the trenched JBS areas may be formed concurrently.

One or more p-type guard rings may be formed in the drift layer 204 in the termination region. In one or more embodiments, each of the guard rings may be formed as part of a trench structure extending partially into the drift layer 204 in the vertical direction and separated from one another in the horizontal direction, and may therefore be referred to herein as trenched guard rings. Each of the trenched guard rings includes p-type trench sidewalls 210 and a p-type trench bottom regions 211. Specifically, a plurality of trenches (i.e., termination region trenches) may be etched into the drift layer 204 in the termination region. A vertical depth of the trenches in the termination region, from the upper surface of the drift layer 204, may be about 0.4 μm-2.0 μm (e.g., about 1.0 μm-1.5 μm) and a width of each of the termination region trenches in the horizontal direction may be about 0.5 μm-2.0 μm (e.g., about 1.0 μm), although embodiments are not limited thereto. The p-type trench sidewalls 210 may be formed on vertical sidewalls of the termination region trenches, for example using a tilted implant process (e.g., about ±10-50 degrees from a line normal to the surface), and the p-type trench bottom regions 211 may be formed on a bottom of the termination region trenches, for example using a vertical implant process.

Like the trenched JBS areas (comprising the p-type trench sidewalls 206 and p-type trench bottom regions 207) and/or the p-type doping area (comprising the p-type trench sidewalls 208 and p-type trench bottom region 209), a fifth doping concentration of the p-type trench sidewalls 210 of the guard rings may be different than a sixth doping concentration of the p-type trench bottom regions 211 of the guard rings. By way of example only and without limitation, in one or more embodiments, the sixth doping concentration of the p-type doping of the trench bottom regions 211 may be comprised of multiple doping levels, including a heavily-doped p-type region and a lighter-doped p-type region which is below the heavily-doped p-type region.

In other embodiments, the sixth doping concentration of the p-type doping of the trench bottom regions 211 may include only a heavily-doped p-type region. The fifth doping concentration of the p-type trench sidewalls 210 may be chosen to be different from the first doping concentration of the p-type trench sidewalls 206, since the doping of the p-type trench sidewalls 210 needs to fully deplete mesas in the termination region (i.e., portion of the drift layer 204 between adjacent trenched guard rings) during a blocking voltage (i.e., reverse-bias) condition. In one or more embodiments, the mesas in the termination region might be made narrower (in the horizontal direction) than the width of the mesas in the active region. In one or more embodiments, the first mesa in the termination region may have a narrower width than the mesas in the active region, with each additional mesa after the first termination region mesa having an incrementally wider width than the previous mesa. In one or more embodiments, the fifth doping concentration of the p-type trench sidewalls 210 may be configured to be the same as the first doping concentration of the p-type trench sidewalls 206, thereby enabling both dopings to be implemented using the same implant process. In one or more embodiments, the sixth doping concentration of the p-type trench sidewalls 211 may be configured to be the same as the first doping concentration of the p-type trench sidewalls 207, thereby enabling both dopings to be implemented using the same implant process.

In one or more embodiments, metal-silicided ohmic contact regions 212 may be provided in the trenched JBS areas, on the p-type trench bottom regions 207 of each of at least a subset of the active region trenches. Although shown as a single layer in FIG. 2 for simplicity, the metal-silicided ohmic contact regions 212 may be formed on the p-type trench bottom regions 207 as a metal silicide on top of the heavily-doped p-type (p+) junction in the p-type trench bottom region 207. The metal silicide in the metal-silicided ohmic contact regions 212 may be formed, in one or more embodiments, using a standard silicidation process. A silicidation process may include depositing a metal (e.g., nickel) on the heavily-doped p-type (p+) junction, followed by annealing to form the metal silicide (e.g., nickel silicide (Ni₂Si)). The metal-silicided ohmic contact regions 212 can be provided in each of the trenched JBS areas or in less than all of the trenched JBS areas (e.g., on every other one of the p-type trench bottom regions 207).

Similarly, a metal-silicided ohmic contact region 214 may be provided on at least a portion of the p-type trench bottom region 209 of the p-type doping area in the transition region. In a manner consistent with the formation of the metal-silicided ohmic contact regions 212 in the active region, the metal-silicided ohmic contact regions 214 may comprise a metal silicide on top of a heavily-doped p-type (p+) junction in p-type trench bottom region 209. In one or more embodiments, the heavily-doped p-type regions 214 may be proximate the p-type trench sidewall 208 of the p-type doping area that is adjacent the active region, leaving a remaining portion of the p-type trench bottom region 209 in the transition region trench free of any heavily-doped p-type region. In other embodiments, the metal-silicided ohmic contact region 214 may be formed on an entirety of the p-type trench bottom region 209, or on a portion of the p-type trench bottom region 209 proximate the p-type trench sidewall 208 adjacent the termination region. The metal-silicided ohmic contact regions 212, 214 may be configured to improve a surge current handling capability in the Schottky diode 200.

An insulating (i.e., dielectric) layer 216 may be formed on a portion of the p-type doping area in the transition region trench, such as on a p-type trench sidewall 208 adjacent the termination region and a portion of the p-type trench bottom region 209 in the transition trench, and on the guard rings in the termination region, such as on the p-type trench sidewalls 210 and the p-type trench bottom region 211 of each of the guard rings. Specifically, in the transition region the insulating layer 216 may be formed on the exposed portion of the p-type trench bottom region 209 that does not include the metal-silicided ohmic contact region 214 formed thereon, and the p-type trench sidewall 208 of the p-type doping area adjacent the termination region. The insulating layer 216 may also be formed on the p-type trench sidewalls 210 and p-type trench bottom region 211 of each of the guard rings, with the insulating layer 216 filling the termination region trenches. The term “filling” (or “fill” or like terms), as may be used herein, is intended to refer broadly to either completely filling a defined space (e.g., the termination region trenches) or partially filling the defined space; that is, the defined space need not be entirely filled but may, for example, be partially filled or have voids or other spaces or materials throughout. The insulating layer 216 may extend horizontally on upper surfaces of the transition region trench and termination region trenches and on a portion of the drift layer 204 in the termination region of the Schottky diode 200. The insulating layer 216 may comprise, for example, an undoped oxide (e.g., silicon dioxide) that is planarized, for example, by chemical-mechanical polishing or a borophosphosilicate glass (BPSG) oxide that is planarized by thermal reflow, although embodiments are not limited thereto.

A metal or metal nitride layer 218 that is appropriate for making a Schottky contact (i.e., Schottky barrier junction) to the n-type drift doping 204 may be provided in the active region, extending horizontally on at least a portion of the upper surface of the drift layer 204, including the drift layer 204 between adjacent active region trenches (i.e., on the active region mesas), and on the p-type trenched sidewalls 206 of the trenched JBS areas (i.e., on the sidewalls of the active region trenches) and on the metal-silicided ohmic contact regions 212 on the p-type trench bottom region 207 of the trenched JBS areas. In a Schottky diode application, the metal-nitride layer 218 may be referred to as a Schottky layer 218.

A Schottky junction will only be formed where the Schottky layer 218 is in contact with the n-type drift doping 204. When the Schottky layer 218 is in contact with the p-type mesa sidewall 206 or 208, only a poor ohmic contact will be formed. When the Schottky layer 218 is in contact with the metal-silicided regions 212 or 214, an ohmic metal-to-metal or metal-nitride-to-metal contact will be formed. The Schottky layer 218 may also be formed on the upper surface of the drift layer 204 extending horizontally into the transition region, on the p-type trench sidewall 208 of the doping area proximate the active region, on an upper surface of the metal-silicided ohmic contact region 214 on a portion of the p-type trench bottom region 209 of the p-type doping area, and on a sidewall of the insulating layer 216 facing the active region.

The Schottky layer 218 may further extend horizontally on a portion of an upper surface of the insulating layer 216 in the transition region. The portion of the Schottky layer 218 extending horizontally on the upper surface of the insulating layer 216 may serve as a field plate configured to redistribute the electric field away from the active region.

The Schottky layer 218 may comprise a material selected to provide a desired work function for the Schottky diode 200. The Schottky layer 218 may comprise, for example, a metal or metal nitride or metal silicide. Suitable materials for use as the Schottky layer 218 may include, for example, molybdenum, platinum, chromium, tungsten, tungsten nitride, titanium, tantalum, titanium nitride, tantalum nitride, although embodiments are not limited to these or any particular materials. The Schottky layer 218 electrically connects to the metal-silicided ohmic contact regions 212 and 214, the trenched JBS areas (including the p-type trench sidewalls 206 and the p-type trench bottom regions 207) and a portion of the p-type doping area (e.g., on the p-type trench sidewall 208 of the transition region trench proximate the active region).

The Schottky diode 200 may further include an anode electrode 220 and a cathode electrode 222. The anode electrode 220 is electrically connected to the Schottky layer 218, extending horizontally on the Schottky layer 218 in the active region and in a portion of the transition region. The anode electrode 220 may at least partially fill the active region trenches and a portion of the transition region trench. The cathode electrode 222 may be formed on a back surface of the substrate 202 and provides electrical contact with the substrate 202.

The Schottky diode 200 may include a passivation layer 224 formed over an upper surface of the Schottky diode 200. Specifically, the passivation layer 224 may be provided on a portion of the anode electrode 220, proximate the transition region and extending horizontally on the upper surface of the insulating layer 216 in the transition and termination regions of the Schottky diode 200. An opening in the passivation layer 224 is provided in at least a portion of the active region through which the anode electrode 220 is exposed for external electrical connection to the Schottky diode 200.

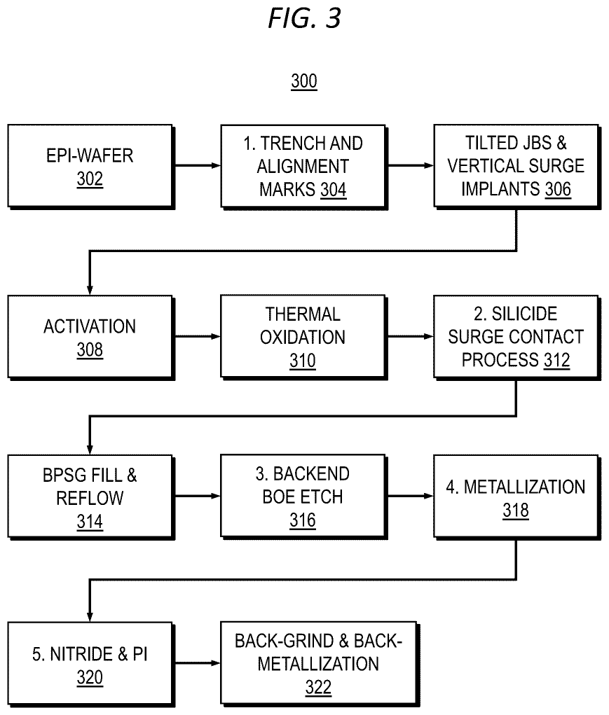

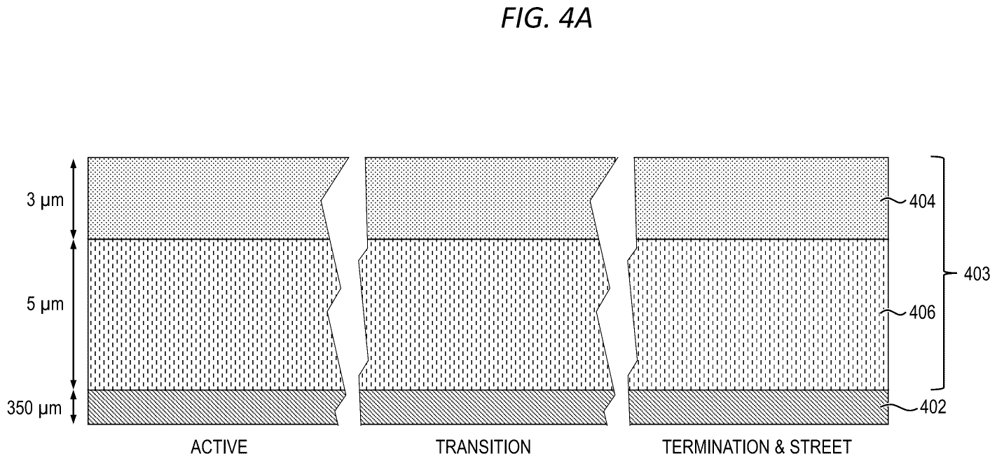

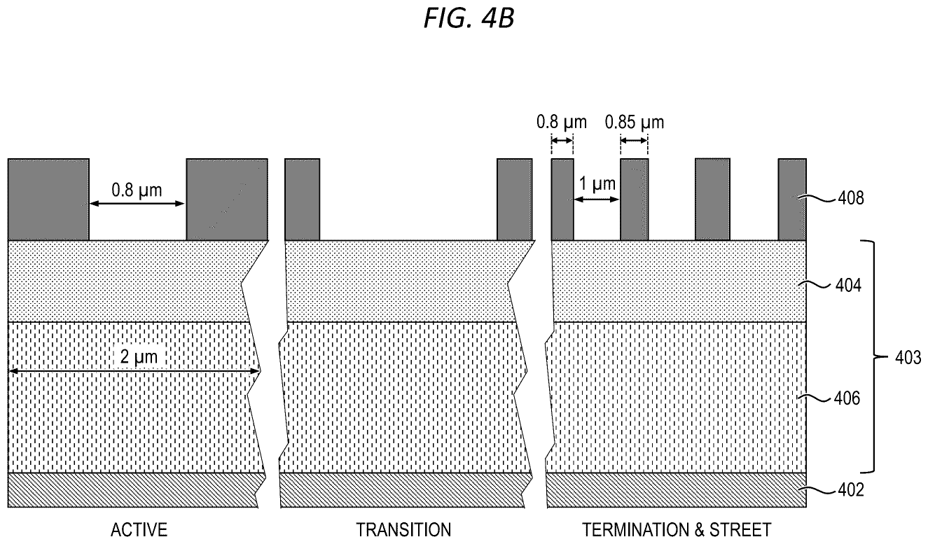

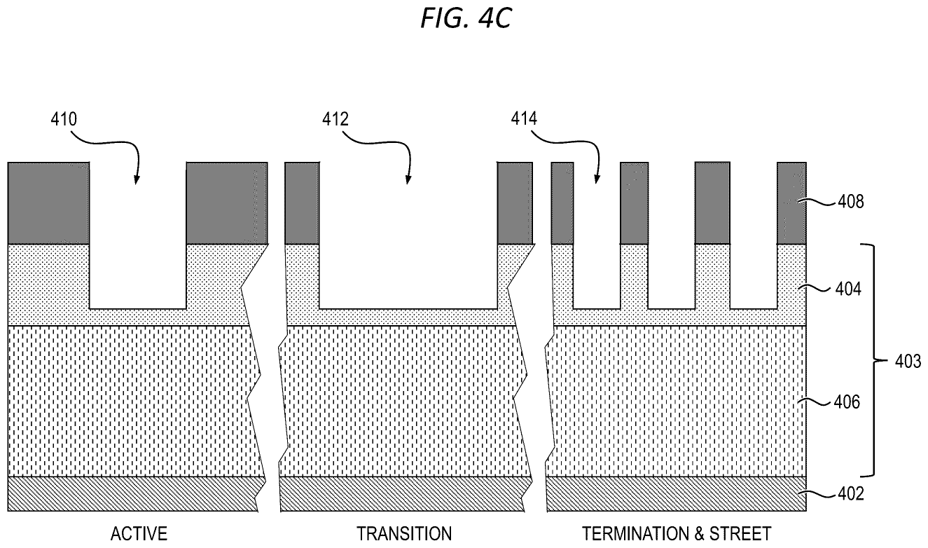

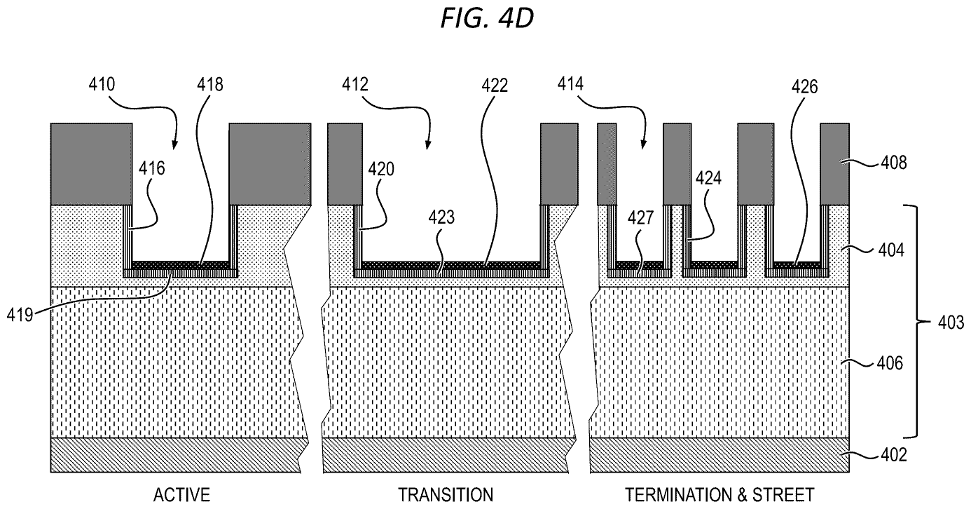

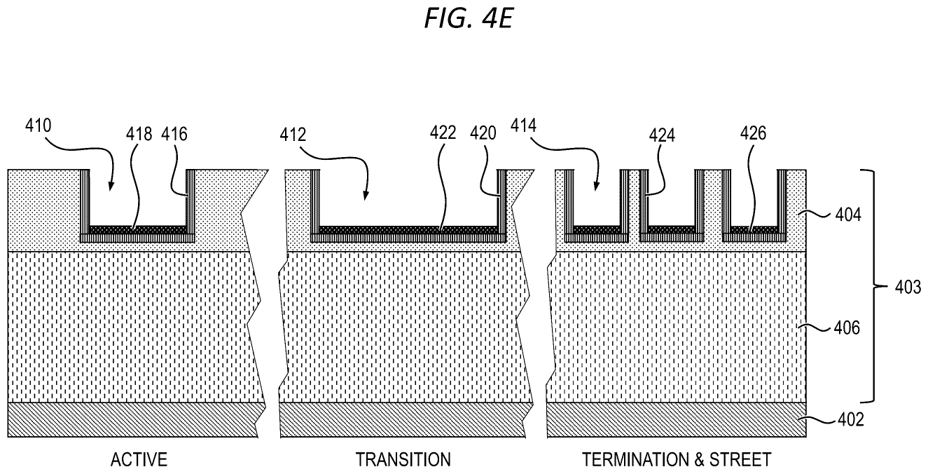

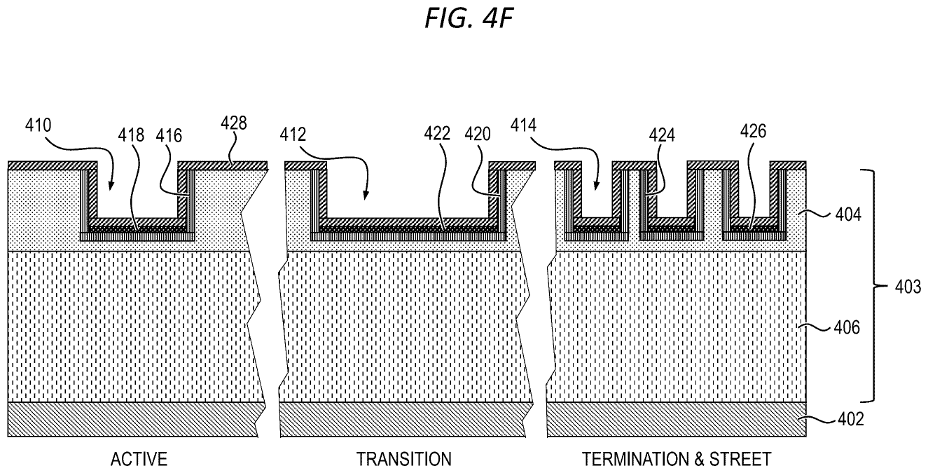

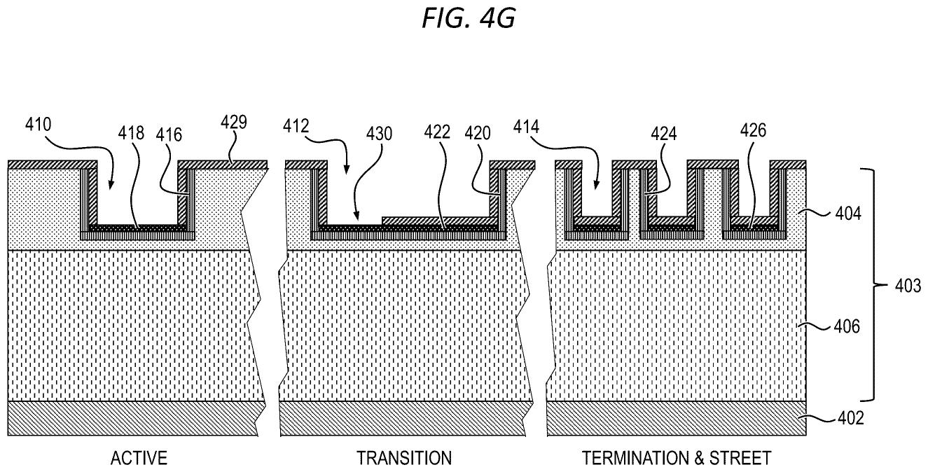

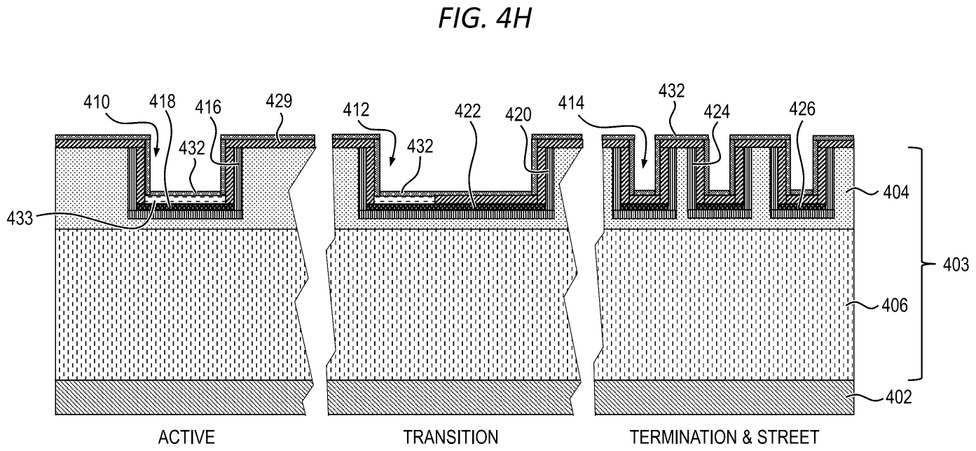

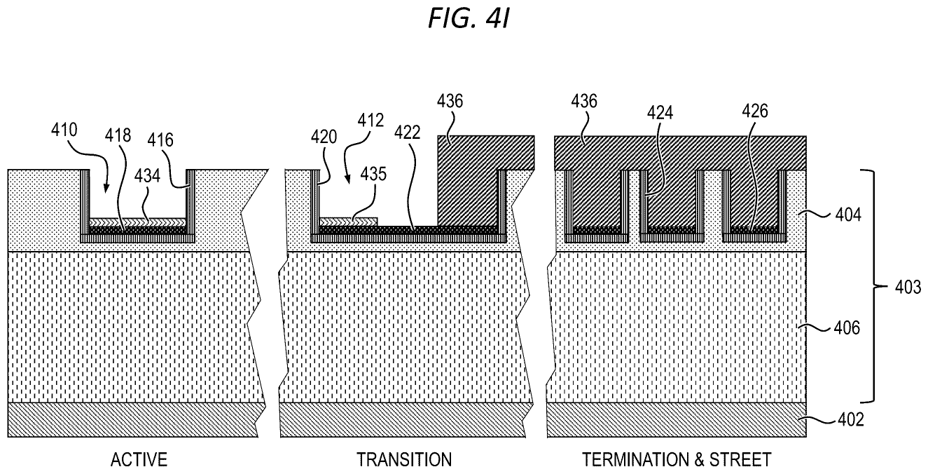

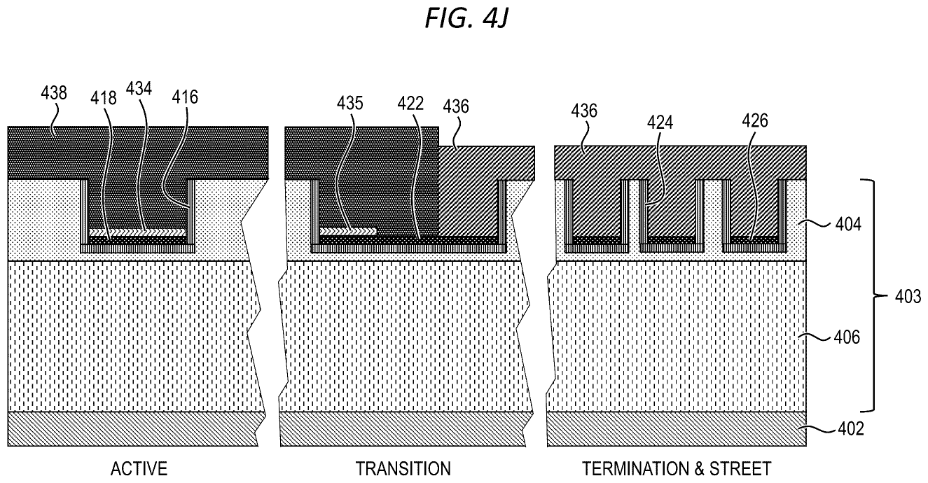

FIG. 3 is a flow diagram depicting intermediate processes in an example method 300 of fabricating a trench diode (e.g., trench Schottky diode 200 shown in FIG. 2), according to one or more embodiments of the inventive concept. FIGS. 4A-4J are schematic cross-sectional views depicting intermediate processes in the example method 300 shown in FIG. 3, according to one or more embodiments of the inventive concept. In FIGS. 4A-4J, only a single active region trench is shown for clarity. It is to be appreciated, however, that the number of active cells (i.e., active region trenches) in the Schottky diode will vary depending on the current capability of the diode needed for a given application.

With reference to FIGS. 3 and 4A, the method 300 includes providing, in step 302, a wafer including a SiC substrate 402 and a drift layer 403 formed on an upper surface of the substrate 402. The substrate 402 may be, for example, an n-type silicon carbide substrate doped with an n-type impurity of a prescribed doping concentration (e.g., about 1 [symbol] 10¹⁰ atoms/cm³), which may serve as a cathode of the Schottky diode. A cross-sectional thickness of the substrate 402 may be about 350 μm and a cross-sectional thickness of the drift layer 403 may be about 8 μm, although embodiments are not limited to any specific dimensions of the substrate 402 or drift layer 403.

In one or more embodiments, an upper portion of the drift layer 404 may be configured having a different doping concentration compared to a lower portion of the drift layer 406. For example, the upper portion of the drift layer 404 may be configured having a first doping concentration of about 5 [symbol] 10¹⁶ atoms/cm³ and the lower portion of the drift layer 406 may be configured having a second doping concentration of about 5 [symbol] 10¹⁵ atoms/cm³, although embodiments are not limited thereto.

The wafer may be divided (i.e., categorized) into certain regions or zones based on the type of devices or structures formed therein, including an active region where one or more active devices (e.g., Schottky diode) are formed, a termination region where device edge termination structures (e.g., guard rings) and streets (e.g., scribe lines, etc.) are formed, and an transition region (e.g., p-type doping area) disposed between the active region and the termination region that serves as doped transition area between the active and termination regions in which one or more transition structures (e.g., a moat termination structure) may be formed. The active region, transition region and termination region are adjacent in a horizontal direction parallel to an upper surface of the substrate 402.

Referring to FIGS. 3 and 4B, in step 304, trench and alignment marks are formed. A mask layer of silicon dioxide (SiO₂), silicon nitride (SiN), or the like, of a prescribed cross-sectional thickness (e.g., about 2.5 μm) is deposited on an upper surface of the wafer. The mask layer of SiO₂ or SiN may be formed using a deposition process, such as, for example, plasma-enhanced chemical vapor deposition (PECVD). This mask layer is then patterned, for example using a standard photolithographic process, to form a first patterned mask 408 on the upper surface of the wafer. The first patterned mask 408, which is shown in FIG. 4B after etching and without a photoresist layer (i.e., with the photoresist layer stripped), includes a plurality of openings which will define the locations of trenches in the active region, transition region and termination region.

By way of example only and without limitation, a horizontal width of the opening(s) in the active region may be about 0.4 μm-1.2 μm (e.g., about 0.8 μm) and a horizontal width of each of the openings in the termination region may be about 0.4 μm-2.0 μm (e.g., about 1.0 μm). It is to be appreciated that only a small portion of the active region of a typical device is shown for clarity purposes, and that the active region is typically much wider than what is shown. For example, a portion of the active region about 0.8 μm-4.0 μm (e.g., about 2.0 μm) in width is illustrated, which may represent a single active region trench. A horizontal distance between adjacent openings (i.e., mesa width) in the termination region may be about 0.4 μm-2.0 μm (e.g., about 0.85 μm), although embodiments are not limited to any specific dimensions. A horizontal width of the opening in the transition region may vary widely depending on the application. For example, the horizontal width of the opening in the transition region may be about 10 μm to about 100 μm or more.

In step 304, trenches may be formed in the upper portion of the drift layer 404 using the first patterned mask 408, as shown in FIG. 4C. Specifically, a plurality of first trenches 410 may be formed in the active region, a second trench 412 may be formed in the transition region, and a plurality of third trenches 414 may be formed in the termination region. Note that only one trench 412 is shown in FIG. 4C (and the following figures) to simplify the drawings. An anisotropic etching process may be used to form the trenches 410, 412, 414, and a vertical depth of each of the trenches 410, 412, 414 in the upper portion of the drift layer 404 may be about 0.4 μm-2.0 μm (e.g., about 1.0 μm-1.5 μm), although embodiments are not limited thereto. While not explicitly shown in the figures, the trench 412 will typically be deeper than the trenches 410, 414 (e.g., about 10-40% deeper) since the wider trench 412 will etch more heavily during the anisotropic etching process.

With reference to FIGS. 3 and 4D, the first patterned mask 408 is used to form a trenched JBS area, a trenched doping area and trenched termination areas in the active region, the transition region and the termination region, respectively. Specifically, a tilted (i.e., angled) implant process may be used to form p-type trench sidewalls 416 on sidewalls of the first trench 410 in the active region. A vertical implant process may be used to form a heavily-doped p-type trench bottom 418 on a bottom of the first trench 410 in the active region. In some embodiments, it may be necessary to form a sidewall spacer on the sidewalls of the first trench 410 prior to performing any vertical implant to prevent lateral implant scatter and thus contamination of the sidewall doping by the vertical implant. Optionally, a lightly doped p-type (p−) region 419 may be formed under the heavily-doped p-type trench bottom 418 in the trenched JBS area in the active region. The p-region 419 may be formed using a vertical implant through the bottom of the first trench 410 having a lower doping concentration than the heavily-doped p-type trench bottom 418.

A tilted implant process may be used to form p-type trench sidewalls 420 on sidewalls of the second trench 412 in the transition region and a vertical implant process may be used to form a heavily-doped p-type trench bottom 422 on a bottom of the second trench 412 in the transition region. In some embodiments, it may be necessary to form a sidewall spacer on the sidewalls of the first trench 410 prior to performing any vertical implant to prevent lateral implant scatter and thus contamination of the sidewall doping by the vertical implant. Optionally, a lightly doped p-type (p−) region 423 may be formed under the heavily-doped p-type trench bottom 422 in the trenched doping area in the transition region. The lightly doped p-type region 423 may be formed using a vertical implant through the bottom of the second trench 412 having a lower doping concentration than the heavily-doped p-type trench bottom 422. Similarly, a tilted implant process may be used to form p-type trench sidewalls 424 on sidewalls of each of the third plurality of trenches 414 and a vertical implant process may be used to form a heavily-doped p-type trench bottom 426 on a bottom of each of the third plurality of trenches 414 in the termination region. The p-type trench sidewalls 424 and heavily-doped p-type trench bottoms 426 on the sidewalls and bottom, respectively, of each of the third plurality of trenches 414 will form respective guard rings in the termination region. In some embodiments, it may be necessary to form a sidewall spacer on the sidewalls of the first trench 410 prior to any vertical implant to prevent lateral implant scatter and thus contamination of the sidewall doping by the vertical implant. Optionally, a lightly doped p-type (p−) region 427 may be formed under the heavily-doped p-type trench bottom 426 in the trenched termination areas in the transition region. The lightly doped p-type region 427 may be formed using a vertical implant through the bottom of the third trenches 414 having a lower doping concentration than the heavily-doped p-type trench bottoms 426.

The tilted and vertical implant process may be performed using, for example, ion implantation, although embodiments are not limited thereto. A first doping concentration may be used for the p-type doping on the sidewalls of the trenches 410, 412, 414 and a second doping concentration may be used for the p-type doping on the bottom of the trenches 410, 412, 414. In one or more embodiments, the first and second doping concentrations may be different. For example, the second doping concentration may be greater than the first doping concentration. The same tilted ion implantation processes may be used to concurrently form the p-type trench sidewalls 416, 420, 424 on the sidewalls of the respective trenches 410, 412, 414, and a single vertical ion implantation process may be used to concurrently form the heavily-doped p-type trench bottom regions 418, 422, 426 on the bottoms of the respective trenches 410, 412, 414. In practice, multiple tilted implants may be used to form the p-type trench sidewalls. For example, a first tilted implant may be used to form the left p-type trench sidewalls 416, 420, 424, and a second tilted implant may be used to form the right p-type trench sidewalls 416, 420, 424. Thus, the doping concentration of the left trench sidewalls may be independently controlled with respect to the doping concentration of the right trench sidewalls. In another example, multiple tilted implants each having different implant energies may be used to create the p-type trench sidewall doping profiles.

Once the tilted and vertical implant processes have been completed in step 306, the first mask pattern 408 may be removed, as shown in FIG. 4E, and activation of the p-type implants may be performed in step 308. The first mask pattern (408 in FIG. 4D) may be removed, for example, using a selective etching process (e.g., an etchant selective to SiO₂ or SiN) or planarization process (e.g., chemical-mechanical polishing (CMP)). The p-type implants may be activated using thermal processing (i.e., heating or annealing). In one or more embodiments, thermal processing may be performed at a temperature of about 1500-1600 degrees Celsius (° C.) in an argon environment, although embodiments are not limited thereto. Although not explicitly shown, a protective layer may be formed on the upper surface of the wafer to prevent damage to the surface layer during thermal processing.

Referring to FIGS. 3 and 4F, an oxide layer (e.g., silicon oxide (SiO) or SiO₂) 428 is grown on the upper surface of the wafer, for example using a thermal oxidation process, in step 310. Thermal oxidation may be performed at a temperature of about 1200° C. In other embodiments, the oxide layer may be deposited using an oxide deposition method such as, for example, PECVD, sub-atomic chemical vapor deposition (SACVD), high-temperature oxide (HTO) deposition, or similar. The oxide layer 428 may conformally cover the sidewalls and bottom of each of the trenches 410, 412, 414 and extend horizontally on the upper surface of the upper portion of the drift layer 404 throughout the active region, transition region and termination region. The term “conformally” (or “conformal” or like terms), as may be used herein in the context of a material layer or coating, is intended to refer broadly to a material layer or coating having a substantially uniform cross-sectional thickness relative to the contour of a surface to which the material layer is applied. The term “cover” (or “covering,” “covers,” or like terms), as may be used herein, is intended to broadly refer to an element, structure or layer that is on or over another element, structure or layer, either directly or with one or more other intervening elements, structures or layers therebetween.

In step 312, a second patterned mask may be formed by selectively patterning the oxide layer 428 (e.g., using a standard photolithographic process). The second patterned mask 429 is shown in FIG. 4G after etching and without a photoresist layer (i.e., with the photoresist layer stripped). More particularly, with reference to FIG. 4G, all or a portion of the oxide layer 428 (see FIG. 4F) may be removed at the bottom of the active region trench 410 using anisotropic etching, thereby exposing at least a portion of the p-type trench bottom 418 of the trenched JBS area on a bottom of the active region trench 410 through the second patterned mask 429. Additionally, the second patterned mask 429 may include an opening 430 in a portion of the transition region trench 412, which may be formed by removing a portion of the oxide layer 428 (see FIG. 4F) such as, for example, by anisotropic etching or the like, leaving the oxide layer on sidewalls of the trenches 410, 412, 414. In the case of the anisotropic etching, the oxide on top of the mesas may be made thicker than the oxide on the bottom of the mesas in order for some of the oxide on top of the mesas to survive the anisotropic etching process. The underlying p-type trench bottom 422 of the trenched doping area at the bottom of the second trench 412 in the transition region will be exposed through the opening 430 in the second mask pattern 429. The opening 430 in the second patterned mask 429 in the transition region trench 412 and the opening in the second patterned mask 429 at the bottom of the active region trench 410 may be positioned where metal silicide regions are desired. Although only a portion of the p-type trench bottom 422 in the transition region (proximate the active region) is exposed, in some embodiments, the entirety of the p-type trench bottom 422 may be exposed through the opening 430 in the second patterned mask 429 in other embodiments. That is, the width and horizontal position of the opening 430 at the bottom of the second trench 412 is not limited to what is shown in FIG. 4G.

With reference to FIGS. 3 and 4H, upper portions of the heavily-doped p-type trench bottom regions 418 and 422 may be converted into metal silicide regions using a silicide process in step 312. In one or more embodiments, a metal layer 432 (e.g., nickel) may be blanket deposited, including on the heavily-doped p-type trench bottom regions 418 and 422 exposed through the second patterned mask 429. A first anneal (e.g., rapid thermal anneal (RTA)) may be performed at a first temperature (e.g., about 600-700° C.) whereby a portion of the deposited metal layer 432 will combine with silicon in the underlying heavily-doped p-type trench bottom regions 418 and 422 to form metal silicide (e.g., nickel silicide). The pure (i.e., unreacted) metal portion of the metal layer 432 is then stripped away and a second anneal is performed at a second temperature (e.g., about 800-950° C.), thereby forming a metal silicide 434 and 435 in the upper portions of the heavily-doped p-type trench bottom regions 418 and 422, respectively, as shown in FIG. 4I. These metal silicide regions are shown in FIG. 4I as well as in FIG. 2 (as regions 212 and 214). The second patterned mask 429 may then be removed.

With continued reference to FIGS. 3 and 4I, in step 314 a dielectric layer may be deposited on the upper surface of the wafer, followed by a reflow process. In one or more embodiments, the dielectric layer may comprise SiO₂ or conformal BPSG, although embodiments are not limited thereto. The dielectric layer may fill the first, second and third trenches (410, 412, 414 in FIG. 4H) and extend horizontally on the upper surface of the wafer. The dielectric layer may be patterned, for example using a photolithographic process, to expose the active region and a portion of the transition region and thereby form a third patterned mask 436. In one or more embodiments, a portion of the transition region proximate the termination region, including a last mesa adjacent to the termination region (i.e., the right-hand side mesa between the transition region and the termination region), will remain covered by the third patterned mask 436, thereby preventing a Schottky contact from being formed on top of the outermost mesa (which is the mesa on the right side of the transition region in FIG. 4I). Since there are no metal silicide regions (i.e., ohmic contacts) at the bottom of the trench P+ regions 422 surrounding the outermost mesa to allow the outermost mesa column adjacent to the termination region to be fully depleted during reverse-bias conditions in order to cut off Schottky leakage current in the device, a Schottky contact should not be formed on the upper surface of the outermost mesa. The third patterned mask 436 is shown in FIG. 4I after etching and without a photoresist layer (i.e., with the photoresist layer stripped).

In step 316, with the third patterned mask 436 in place to protect the termination region and the portion of the transition region adjacent the termination region (i.e., the right-hand portion of the transition region), an etching process, such as, for example, a backend buffered oxide etch (BOE), may be performed to expose the tops of the mesas in the active region and on the mesa top at the inner side of the transition region proximate the active region, the p-type trench sidewalls 416, one of the p-type trench sidewalls 420 in the transition region, and the metal silicide regions 434, 435 of the heavily-doped p-type trench bottom regions 418, 422 in the active region and in the transition region.

In step 318, a metallization process is performed. Referring to FIGS. 3 and 4J, during metallization, a metal layer 438 is deposited to fill the first trench 410 (see FIG. 4I) in the active region and the second trench 412 (see FIG. 4I) in the transition region and extend horizontally on the upper surface of the wafer in the active and transition regions. The metal layer 438 may comprise a single-layer structure or, in some embodiments, may comprise a multi-layer structure. For a Schottky diode embodiment, the metal layer 438 may form the Schottky contact (i.e., Schottky barrier) and the anode electrode. In one or more embodiments, the type of metal used for the Schottky contact may be different from the type of metal used for the anode electrode, as shown, for example, in FIG. 2. As such, in some embodiments step 318 may involve a first metal deposition for forming the Schottky contact (e.g., 218 in FIG. 2) and a second metal deposition for forming the anode electrode and trench doping area connection (e.g., 220 in FIG. 2).

The metal layer 438 may comprise, for example, aluminum or copper, although embodiments are not limited thereto. In order to reduce voids when filling the active region and transition region trenches 410, 412 with the metal layer 438, a high-temperature metal deposition process may be used (e.g., high temperature sputtering, copper plating, etc.). The metal layer 438 may be patterned in step 318 using a fourth mask pattern to form the anode electrode in the active region and an electrical connection to the p-type ohmic contact 435 in the transition region.

Although not explicitly shown in FIG. 4J, a silicon nitride layer and passivation layer (e.g., polyimide) may be deposited on the upper surface of the wafer in step 320 (e.g., 224 in FIG. 2). A fifth mask pattern may be used to pattern the silicon nitride and passivation layers. For example, in one or more embodiments the fifth mask pattern may be used to open a portion of the passivation layer to provide access to the Schottky anode electrode 438 (see, e.g., FIG. 2).

In step 322, a cathode electrode of the Schottky diode may be formed (e.g., 222 in FIG. 2). The substrate 402 may first be thinned using, for example, a back-grind process. After thinning the substrate 402, a back-metallization process may be performed. During back-metallization, a metal layer (e.g., 222 in FIG. 2) may be deposited on the back surface of the substrate 402 to form the cathode electrode which provides electrical connection to the substrate 402. A laser anneal process may be performed as part of the back-metallization process to provide localized heating for forming a silicide after the metal layer has been deposited on the back surface of the substrate 402. In some embodiments, additional metal layers may be optionally deposited on the formed silicide layer on the back surface of the substrate 402 for providing die backside electrical and/or mechanical bondability adapted to a variety of mounting applications.

In accordance with aspects of the inventive concept, a semiconductor device and fabrication method are provided that integrates a trenched active region, MPS ohmic contacts in a transition region and trenched floating guard rings in a termination region to form a SiC diode. Embodiments of the invention achieve such device integration using a reduced number of masks compared to standard approaches. For example, in one or more embodiments, an alignment mask is omitted and instead a trench etch is used for alignment in subsequent processes.

Another advantage of the Schottky diode 200 of FIG. 2 as compared to the Schottky diode 100 of FIG. 1 is that the metal-silicided ohmic contact regions 212, 214 are recessed into the drift region 204 (i.e., well below the upper surface of the drift region 204). As such, during a surge event, the surge currents may only need travel through a thin layer of more lightly-doped p-type material 207, 209 to reach the metal-silicided ohmic contact regions 212, 214 and pass to the anode electrode 220. Since lightly-doped p-type silicon carbide has a relatively high resistance, the Schottky diode 100 of FIG. 1 will heat up more during a surge event as the surge currents pass through relatively thick lightly-doped p-type layers. The Schottky diode 200 of FIG. 2 will not heat up to the same extent, and hence will be more likely to survive surge events without damage.

In the description above, each example embodiment is described as having a certain conductivity type. It will be appreciated, however, that opposite conductivity type devices may be formed by simply reversing the conductivity of the n-type and p-type layers in each of the above embodiments. Thus, it will be understood that the present invention covers both n-type and p-type devices for each different device structure (e.g., Schottky diode, MOSFET, IGBT, etc.).

The present inventive concept has primarily been described above with respect to silicon carbide based power semiconductor devices. It will be appreciated, however, that silicon carbide is used herein as an example and that the devices discussed herein may be formed in any appropriate wide band-gap semiconductor material environment. As an example, gallium nitride based semiconductor materials (e.g., gallium nitride, aluminum gallium nitride, etc.) may be used instead of silicon carbide in any of the embodiments described above.

Embodiments of the present invention have been described above with reference to the accompanying drawings, in which embodiments of the invention are shown. It will be appreciated, however, that this invention may be embodied in many different forms and should not be construed as limited to the embodiments shown and set forth above. Rather, these embodiments are provided so that this disclosure will be thorough and complete, and will fully convey the scope of the inventive concept to those skilled in the art.

Herein, the term “plurality” means two or more. Herein, the term “substantially” means within about ±10%.

It will be understood that, although the ordinal terms such as first, second, etc., may be used throughout this specification to describe various elements, these elements should not be limited by such terms. These terms are used merely to distinguish one element from another and are not intended to convey any particular order of the elements unless specifically stated otherwise. For example, a first element could be termed a second element, and, similarly, a second element could be termed a first element, without departing from the scope of the present disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above,” “upper” or “lower,” “top” or “bottom,” and the like, may be used herein to describe a relationship of one element, layer or region to another element, layer or region as illustrated in the accompanying figures. It will be understood, however, that these terms are intended to encompass different orientations of the device in addition to the orientation depicted in the figures.

Embodiments of the invention are described herein with reference to plan views and cross-sectional views that are schematic illustrations of idealized embodiments (and intermediate structures) of the invention. The dimensions (e.g., thickness, width, length, etc.) of layers and regions depicted in the drawings may be exaggerated for clarity. Additionally, variations from the shapes of the illustrations as a result, for example, of manufacturing techniques and/or tolerances, are to be expected and are within the scope of the inventive concept.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some materials may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region, and does not imply a particular polarity of the layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A Schottky diode, comprising:
a drift layer of a first conductivity type;
a trench in the drift layer;
first implanted regions having a second conductivity type in sidewalls of the trench;
a second implanted region having the second conductivity type in a bottom of the trench; and
a metal in the trench,
wherein the first implanted regions have a first doping concentration and the second implanted region has a second doping concentration, where the first doping concentration is different than the second doping concentration.

2. The Schottky diode according to claim 1, wherein the first implanted regions in the sidewalls of the trench and the second implanted region in the bottom of the trench form a trenched junction barrier Schottky (JBS) area proximate an upper surface of the drift layer and partially in the drift layer in a vertical direction perpendicular to an upper surface of the drift layer.

3. The Schottky diode according to claim 1, wherein the drift layer comprises first and second mesas that define the sidewalls of the trench, and wherein the metal is on upper surfaces of the first and second mesas to form Schottky contacts.

4. The Schottky diode according to claim 3, further comprising:
a substrate of the first conductivity type, the drift layer being on an upper surface of the substrate;
an anode electrode on at least a portion of the Schottky contact and electrically connected to the Schottky contact; and
a cathode electrode on at least a portion of a back surface of the substrate and electrically connected to the substrate.

5. The Schottky diode according to claim 1, further comprising an ohmic contact on a bottom of the trench between the second implanted region and the metal.

6. The Schottky diode according to claim 1, wherein the drift layer comprises a lower portion and an upper portion on the lower portion of the drift layer, the upper and lower portions of the drift layer having different doping concentrations.

7. The Schottky diode according to claim 6, wherein the lower portion of the drift layer has a third doping concentration and the upper portion of the drift layer has a fourth doping concentration, the fourth doping concentration being greater than the third doping concentration.

8. The Schottky diode according to claim 6, wherein the trench is partially in the upper portion of the drift layer in a vertical direction perpendicular to the upper surface of the drift layer.

9. The Schottky diode according to claim 1, wherein the drift layer comprises an active region, a transition region and a termination region adjacent in a horizontal direction parallel to the upper surface of the drift layer, and wherein the trench in the upper surface of the drift layer comprises:
a trenched junction barrier Schottky (JBS) area of the second conductivity type proximate the upper surface of the drift layer and partially in the active region of the drift layer;
a trenched doping area of the second conductivity type proximate the upper surface of the drift layer and partially in the transition region of the drift layer; and
a plurality of trenched guard rings of the second conductivity type proximate the upper surface of the drift layer and partially in the termination region of the drift layer.

10. The Schottky diode according to claim 9, further comprising an ohmic contact on at least a portion of a bottom of the trenched doping area.

11. The Schottky diode according to claim 10, wherein the metal extends on a sidewall of the trenched doping area proximate the active region and on the ohmic contact on the bottom of the trenched doping area.

12. The Schottky diode according to claim 9, wherein the trenched doping area and each of the plurality trenched guard rings are at least partially filled with an insulating layer.

13. The Schottky diode according to claim 12, wherein the metal extends on a sidewall of the trenched doping area proximate the active region, a portion of a bottom of the trenched doping area, a sidewall of the insulating layer facing the active region, and a portion of an upper surface of the insulating layer in the transition region.

14. The Schottky diode according to claim 1, wherein the trench comprises a plurality of trenched JBS areas in an active region of the drift layer and spaced apart from each other in a horizontal direction parallel to the upper surface of the drift layer.

15. A method of forming a Schottky diode, the method comprising:
providing a drift layer of a first conductivity type on a substrate;
forming a trench in the drift layer;
implanting sidewalls of the trench at a first doping concentration to form first implanted regions;
implanting a bottom of the trench at a second doping concentration to form a second implanted region, wherein the first doping concentration is different than the second doping concentration; and
forming a Schottky contact.

16. The method according to claim 15, wherein the first implanted regions are formed by implanting the sidewalls of the trench with a dopant at the first doping concentration, and the second implanted region is formed by implanting the bottom of the trench with the dopant at the second doping concentration.

17. The method according to claim 15, wherein the drift layer comprises an active region, a transition region and a termination region adjacent in a direction parallel to the upper surface of the substrate, wherein the trench comprises a trenched junction barrier Schottky (JBS) area formed in the active region, and wherein the method further comprises forming a plurality of trenched guard rings in the termination region, the trenched JBS area and the plurality of trenched guard rings being formed during a same processing step.

18. The method according to claim 15, wherein forming the Schottky contact comprises depositing a metal on at least a portion of the upper surface of the drift layer.

19. The method according to claim 15, wherein forming each of the first implanted regions on the sidewalls of the trench further comprises performing a tilted ion implantation process, and forming the second implanted region on the bottom of the trench comprises performing a straight ion implantation process.

20. The method according to claim 15, further comprising:
forming an anode electrode on at least a portion of the Schottky contact and electrically connected to the Schottky contact; and
forming a cathode electrode on at least a portion of a back surface of the substrate and electrically connected to the substrate.

21. The method according to claim 15, further comprising forming an ohmic contact on the bottom of the trench between the second implanted region and the Schottky contact.

22. The method according to claim 15, wherein the drift layer comprises a lower portion on the substrate and an upper portion on the lower portion of the drift layer, the upper and lower portions of the drift layer having different doping concentrations.

23. The method according to claim 22, wherein the trench is partially in the upper portion of the drift layer in a direction perpendicular to an upper surface of the substrate.

24. The method according to claim 15, wherein the drift layer comprises an active region, a transition region and a termination region adjacent in a direction parallel to the upper surface of the substrate, and wherein the method further comprises:
forming a trenched doping area of the second conductivity type proximate the upper surface of the drift layer and partially in the transition region of the drift layer; and
forming a plurality of trenched guard rings of the second conductivity type proximate the upper surface of the drift layer and partially in the termination region of the drift layer.

25.-37. (canceled)

38. A semiconductor device, comprising:
a semiconductor layer structure that comprises a drift layer of a first conductivity type, the semiconductor layer structure comprising an active region, a transition region and a termination region respectively adjacent in a first direction parallel to an upper surface of the semiconductor layer structure;
a first trench in the semiconductor layer structure in the active region;
a second trench in the semiconductor layer structure in the transition region;
a plurality of third trenches in the semiconductor layer structure in the termination region;
first implanted regions having a second conductivity type in sidewalls of each of the first, second and third trenches;
second implanted region having the second conductivity type in a bottom of each of the first, second and third trenches; and
a metal in the first trench and in a portion of the second trench,
wherein the metal is on one of the first implanted regions in the second trench proximate the active region and on a portion of the second implanted region in the second trench, and wherein the second trench is partially filled with a dielectric layer.

39.-50. (canceled)
